(19) United States
(12) Patent Application Publication
(10) Pub. No.: US 2003/0013319 A1
(43) Pub. Date: Jan. 16, 2003

(54) Semiconductor structure with selective doping and process for fabrication

(75) Inventors: John E. Holmes, Scottsdale, AZ (US); Kurt W. Eisenbeiser, Tempe, AZ (US); Rudy M. Emrick, Gilbert, AZ (US); Steven James Franson, Scottsdale, AZ (US); Stephen Kent Rockwell, Mesa, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL (US)

(21) Appl. No.: 09/901,110

(22) Filed: Jul. 10, 2001

(51) Int. Cl. H01L 21/31; H01L 21/469; H01L 21/20; H01L 21/36

(52) U.S. Cl. 438/761; 438/778; 438/482; 257/635

(57) ABSTRACT

A semiconductor structure with selective doping includes a monocrystalline silicon substrate, an amorphous oxide material overlying the monocrystalline silicon substrate, a monocrystalline perovskite oxide material overlying the amorphous oxide material, at least one monocrystalline compound semiconductor material overlying the monocrystalline perovskite oxide material, and a transistor in the at least one monocrystalline compound semiconductor material and including active regions having different conductivity levels under substantially identical bias conditions.

### FIELD OF THE INVENTION

This invention relates generally to semiconductor structures and devices and to a method for their fabrication, and more specifically to semiconductor structures and devices and to the fabrication and use of semiconductor structures, devices, and integrated circuits that include a monocrystalline material layer comprised of semiconductor material, compound semiconductor material, and/or other types of material such as metals and non-metals, and that further includes selective doping within the compound semiconductor material.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material.

Furthermore, a transistor used in a high power and/or high frequency application often has a large number of gate fingers or electrodes overlying a large number of channels. The large number of gate fingers produces a large periphery for the transistor. The parameters defining a large periphery can include, for example, the length of the individual gate fingers and the operating frequency of the transistor. A transistor with a large periphery, however, has several problems.

A first one of these problems is the non-uniform operating temperature across the transistor. In general, a middle or central portion of the transistor has a higher operating temperature than an edge or side portion of the transistor. Consequently, any heat-related lifetime or operating failures that may occur within the transistor typically originate at the middle or central portion of the transistor.

A second one of the problems with a transistor having a large periphery is the uneven or unbalanced current across the transistor. The non-uniform temperature across the transistor contributes to the problem of uneven current distribution across the transistor. In particular, the hotter portion of the transistor will conduct higher levels of current. Therefore, any current-related lifetime or operating failures that may occur within the transistor typically originate at the middle or central portion of the transistor

A third one of the problems with a transistor having a large periphery is the phase imbalance within the transistor. The phase imbalance is due to the different transmission lengths within the transistor from an input of the transistor across the various channels of the transistor to an output of the transistor. This phase imbalance degrades the output power of the transistor.

Accordingly, a need exists for a semiconductor structure that provides a high quality monocrystalline film or layer over another monocrystalline material and for a process for making such a structure. In other words, there is a need for providing the formation of a monocrystalline substrate that is compliant with a high quality monocrystalline material layer so that true two-dimensional growth can be achieved for the formation of quality semiconductor structures, devices and integrated circuits having grown monocrystalline film having the same crystal orientation as an underlying substrate. This monocrystalline material layer may be comprised of a semiconductor material, a compound semiconductor material, and other types of material such as metals and non-metals. A need also exists for the semiconductor structure to have transistors with improved temperature and current distribution across the transistors for increased operating lifetimes and improved reliability. A need further exists for the semiconductor structure to have transistors with reduced phased imbalance across the transistors for higher output power.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-12 illustrate schematically, in cross-section, the formation of a device structure in accordance with another embodiment of the invention;

FIGS. 13-16 illustrate a probable molecular bonding structure of the device structures illustrated in FIGS. 9-12;

FIGS. 17-20 illustrate schematically, in cross-section, the formation of a device structure in accordance with still another embodiment of the invention;

FIGS. 21-23 illustrate schematically, in cross-section, the formation of another embodiment of a device structure in accordance with the invention;

FIGS. 21-23 illustrate schematically, in cross section, the formation of a yet another embodiment of a device structure in accordance with the invention;

FIGS. 24 and 25 illustrate schematically, in cross section, device structures that can be used in accordance with various embodiments of the invention;

FIGS. 26-30 illustrate cross-sectional views of a portion of an integrated circuit that includes a compound semiconductor portion, a bipolar portion, and an MOS portion in accordance with what is shown herein;

FIG. 31 illustrates schematically a top view of an embodiment of a semiconductor structure in accordance with the invention;

FIG. 32 illustrates schematically a partial cross-sectional view of the semiconductor structure of FIG. 31 taken along a section line 31-31 in FIG. 31 in accordance with the invention;

FIGS. 33-37 illustrate schematically cross-sectional views of different embodiments of a compound semiconductor portion of the semiconductor structure of FIGS. 31 and 32 in accordance with the invention; and

FIG. 38 illustrates a flow chart of an embodiment of a process for fabricating a semiconductor structure with selective doping.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention. Additionally, for simplicity and clarity of illustration, the figures illustrate the general manner of construction, and descriptions and details of well-known features and techniques are omitted to avoid unnecessarily obscuring the invention. Furthermore, the terms first, second, third, fourth, fifth, sixth, and the like in the description and in the claims, if any, are (1) used for distinguishing between similar elements and not necessarily for describing a sequential or chronological order and (2) interchangeable under appropriate circumstances such that the embodiments of the invention described herein are, for example, capable of operation in other sequences than described or illustrated herein. Moreover, the terms top, bottom, over, under, and the like in the description and in the claims, if any, are (1) used for descriptive purposes, (2) not necessarily for describing permanent relative positions, and (3) interchangeable under appropriate circumstances such that the embodiments of the invention described herein are, for example, capable of operation in other orientations than described or illustrated herein.

### DETAILED DESCRIPTION OF THE DRAWINGS

FIG. 1 illustrates schematically, in cross section, a portion of a semiconductor structure 20 in accordance with an embodiment of the invention. Semiconductor structure 20 includes a monocrystalline substrate 22, an accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous interface layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous interface layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table, and preferably a material from Group IVB, e.g., Carbon, Silicon, etc. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous interface layer 28 is grown on substrate 22 at the interface between substrate 22 and the growing accommodating buffer layer by the oxidation of substrate 22 during the growth of layer 24. The amorphous interface layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous interface layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. However, monocrystalline material layer 26 may also comprise other semiconductor materials, metals, or non-metal materials which are used in the formation of semiconductor structures, devices and/or integrated circuits.

Appropriate materials for template layer 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

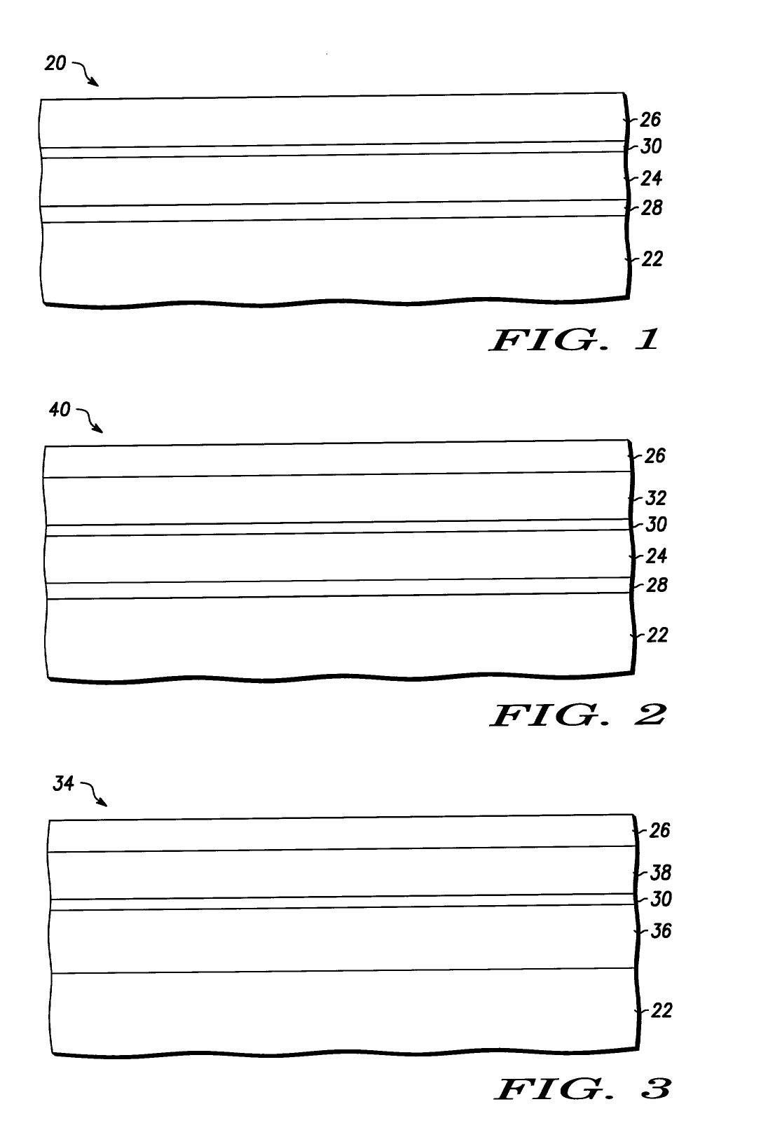

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between substrate 22 and layer 38 and provides a true compliant substrate for subsequent processing—e.g, monocrystalline material layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 millimeters (mm). In accordance with this embodiment of the invention, accommodating buffer layer 24 is a monocrystalline layer of Sr₂Ba_{1-z}TiO₃ where z ranges from 0 to 1 and the amorphous interface layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous interface layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous interface layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45 degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45 degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa_{1-z}TiO₃, where x ranges from 0 to 1, having a thickness of about 2-100 nm and preferably a thickness of about 5-15 nm. Where the monocrystalline layer comprises a compound semiconductor material, the II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1-10 monolayers of strontium-sulfur (Sr—S) followed by the ZnSeS.

### EXAMPLE 4

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 2. Substrate 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The additional buffer layer 32 preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate 22, template layer 30, and monocrystalline material layer 26 may be the same as those described above in connection with example 1.

Amorphous layer 36 is an amorphous oxide layer which is suitably formed of a combination of amorphous interface layer materials (e.g., layer 28 materials as described above) and accommodating buffer layer materials (e.g., layer 24 materials as described above). For example, amorphous layer 36 may include a combination of SiOₓ and Sr_{z}Ba_{1-z}TiO₃ (where z ranges from 0 to 1),which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

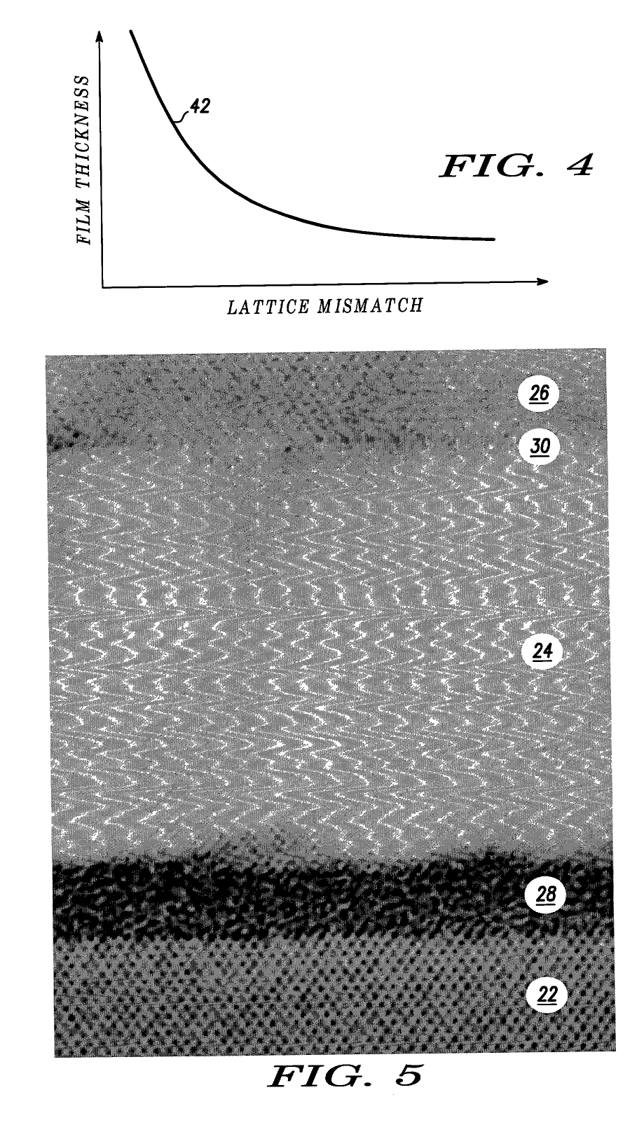

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 850° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 850° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide interface layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interface layer 28 is formed which relieves strain due to lattice mismatch. GaAs compound semiconductor layer 26 was then grown epitaxially using template layer 30.

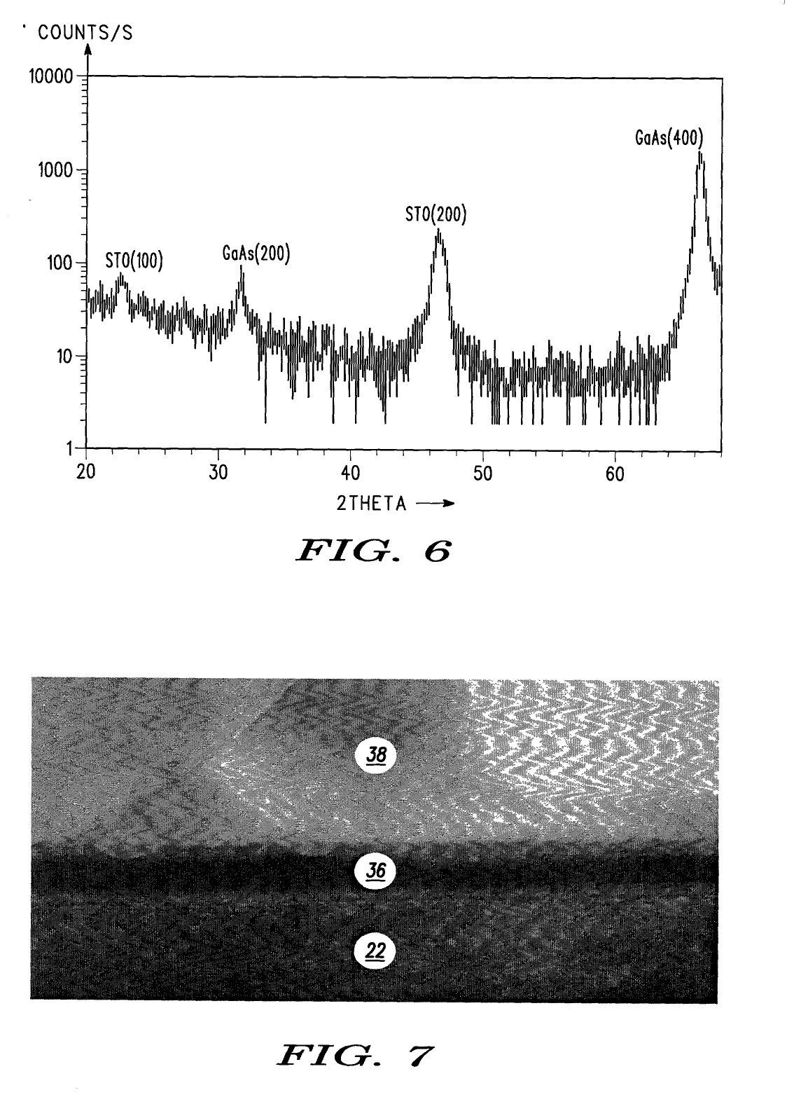

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing monocrystalline layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 7 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

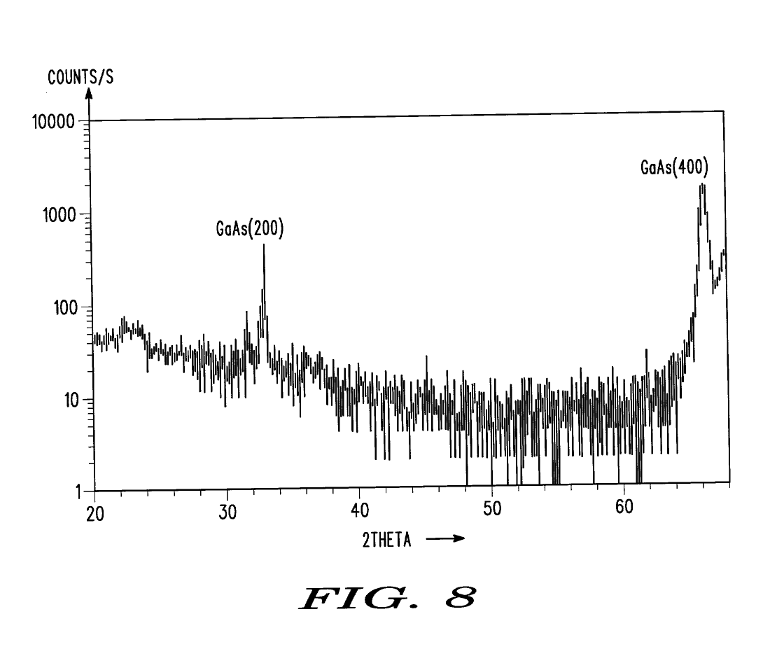

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor material in layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium is titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

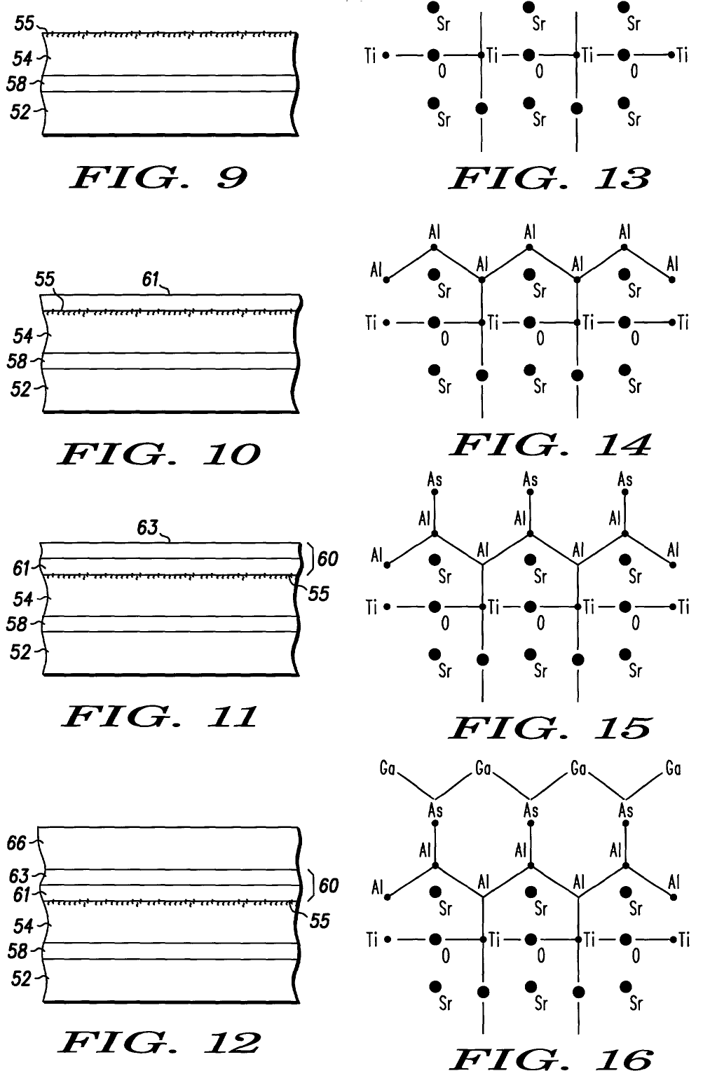

The formation of a device structure in accordance with another embodiment of the invention is illustrated schematically in cross-section in FIGS. 9-12. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9-12 utilizes a template that includes a surfactant to facilitate layer-by-layer monocrystalline material growth.

Turning now to FIG. 9, an amorphous interface layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 1-2 and any of those compounds previously described with reference to layer 36 in FIG. 3 which is formed from layers 24 and 28 referenced in FIGS. 1 and 2.

Layer 54 is grown with a strontium (Sr) terminated surface represented in FIG. 9 by hatched line 55 which is followed by the addition of a template layer 60 which includes a surfactant layer 61 and capping layer 63 as illustrated in FIGS. 10 and 11. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 10 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 11. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 12.

FIGS. 13-16 illustrate possible molecular bond structures for a specific example of a compound semiconductor structure formed in accordance with the embodiment of the invention illustrated in FIGS. 9-12. More specifically, FIGS. 13-16 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layer 28 and substrate 22, respectively in FIGS. 1 and 2, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ_{INT}+δ_{GaAs})

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 10-12, to increase the surface energy of the monocrystalline oxide layer 54 and also to shift the crystalline structure of the template to a diamond-like structure that is in compliance with the original GaAs layer.

FIG. 13 illustrates the molecular bond structure of a strontium terminated surface of a strontium titanate monocrystalline oxide layer. An aluminum surfactant layer is deposited on top of the strontium terminated surface and bonds with that surface as illustrated in FIG. 14, which reacts to form a capping layer comprising a monolayer of Al₂Sr having the molecular bond structure illustrated in FIG. 14 which forms a diamond-like structure with an sp³ hybrid terminated surface that is compliant with compound semiconductors such as GaAs. The structure is then exposed to As to form a layer of AlAs as shown in FIG. 15. GaAs is then deposited to complete the molecular bond structure illustrated in FIG. 16 which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

Turning now to FIGS. 17-20, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 17. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 18 with a thickness of a few hundred Angstroms but preferably with a thickness of about 50 Angstroms. Monocrystalline oxide layer 74 preferably has a thickness of about 20 to 100 Angstroms.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphize the monocrystalline oxide layer 74 into a silicate amorphous layer 86 and carbonize the top silicon layer 81 to form capping layer 82 which in this example would be a silicon carbide (SiC) layer as illustrated in FIG. 19. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an interface single crystal oxide layer that is amorphosized to form a silicate layer which adsorbs the strain between the layers. Moreover, unlike past use of a SiC substrate, this embodiment of the invention is not limited by wafer size which is usually less than 50 mm in diameter for prior art SiC substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

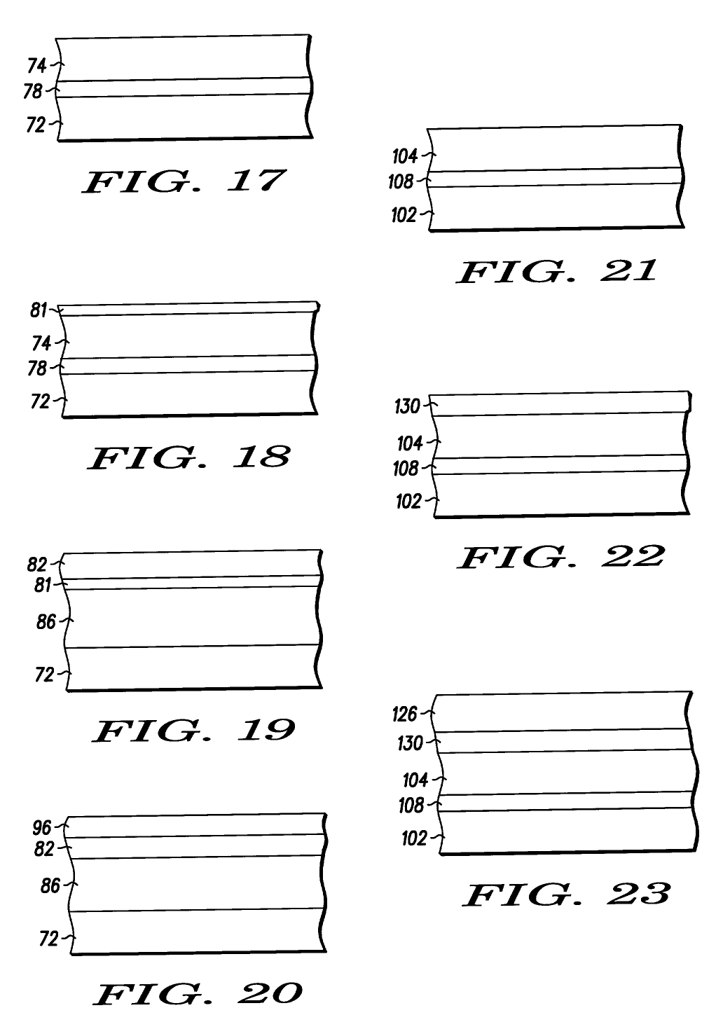

FIGS. 21-23 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 21 includes a monocrystalline substrate 102, an amorphous interface layer 108 and an accommodating buffer layer 104. Amorphous interface layer 108 is formed on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2. Substrate 102 is preferably silicon but may also comprise any of those materials previously described with reference to substrate 22 in FIGS. 1-3.

A template layer 130 is deposited over accommodating buffer layer 104 as illustrated in FIG. 22 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂

A monocrystalline material layer 126 is epitaxially grown over template layer 130 to achieve the final structure illustrated in FIG. 23. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

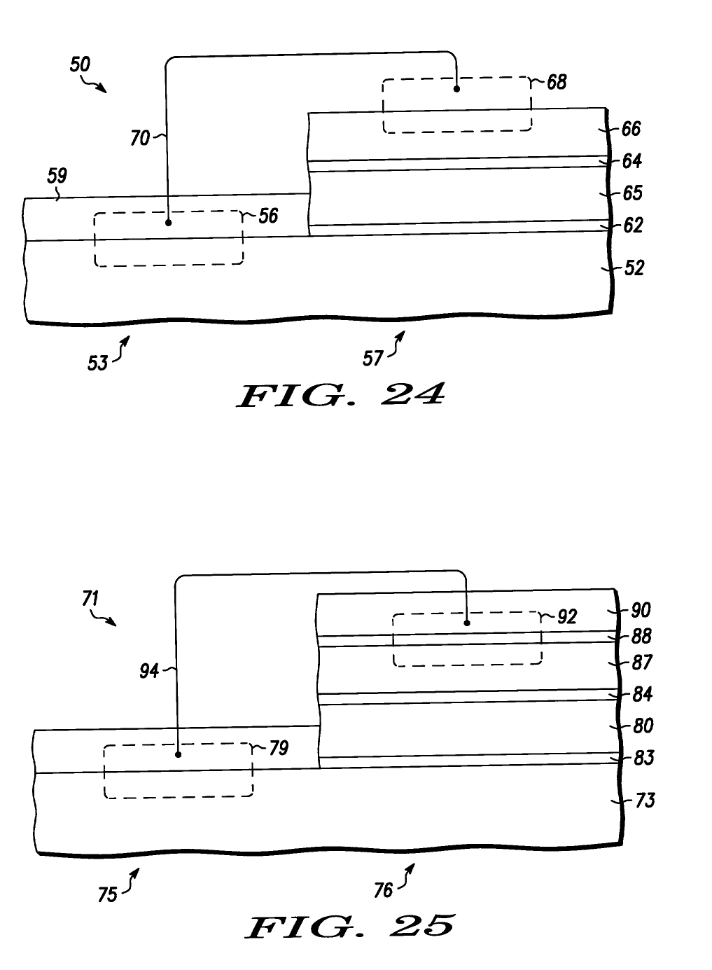

FIG. 24 illustrates schematically, in cross section, a device structure 50 in accordance with a further embodiment. Device structure 50 includes a monocrystalline semiconductor substrate 52, preferably a monocrystalline silicon wafer. Monocrystalline semiconductor substrate 52 includes two regions, 53 and 57. An electrical semiconductor component generally indicated by the dashed line 56 is formed, at least partially, in region 53. Electrical component 56 can be a passive device such as, for example, a resistor, a capacitor, an inductor, or an antenna; an active semiconductor component such as, for example, a diode or a transistor; or an integrated circuit such as, for example, a CMOS or BiCMOS integrated circuit. For example, electrical semiconductor component 56 can be a CMOS integrated circuit configured to perform digital signal processing or another function for which silicon integrated circuits are well suited. The electrical semiconductor component in region 53 can be formed by conventional semiconductor processing as well known and widely practiced in the semiconductor industry. A layer of insulating material 59 such as a layer of silicon dioxide or the like may overlie electrical semiconductor component 56.

Insulating material 59 and any other layers that may have been formed or deposited during the processing of semiconductor component 56 in region 53 are removed from the surface of a region 57 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of region 57 and is reacted with the oxidized surface to form a first template layer (not shown). In accordance with one embodiment, a monocrystalline oxide layer is formed overlying the template layer by a process of molecular beam epitaxy. Reactants including barium, titanium and oxygen are deposited onto the template layer to form the monocrystalline oxide layer. Initially during the deposition the partial pressure of oxygen is kept near the minimum necessary to fully react with the barium and titanium to form monocrystalline barium titanate layer. The partial pressure of oxygen is then increased to provide an overpressure of oxygen and to allow oxygen to diffuse through the growing monocrystalline oxide layer. The oxygen diffusing through the barium titanate reacts with silicon at the surface of region 57 to form an amorphous layer 62 of silicon oxide on region 57 and at the interface between silicon substrate 52 and the monocrystalline oxide layer 65. Layers 65 and 62 may be subject to an annealing process as described above in connection with FIG. 3 to form a single amorphous accommodating layer.

In accordance with an embodiment, the step of depositing the monocrystalline oxide layer 65 is terminated by depositing a second template layer 64, which can be 1-10 monolayers of titanium, barium, barium and oxygen, or titanium and oxygen. A layer 66 of a monocrystalline compound semiconductor material is then deposited overlying second template layer 64 by a process of molecular beam epitaxy. The deposition of layer 66 is initiated by depositing a layer of arsenic onto template 64. This initial step is followed by depositing gallium and arsenic to form monocrystalline gallium arsenide for layer 66. Alternatively, strontium can be substituted for barium in the above example.

In accordance with a further embodiment, a semiconductor component, generally indicated by a dashed line 68 is formed, at least partially, in compound semiconductor layer 66. Semiconductor component 68 can be formed by processing steps conventionally used in the fabrication of gallium arsenide or other III-V compound semiconductor material devices. Semiconductor component 68 can be any active or passive component, and preferably is a semiconductor laser, light emitting diode, photodetector, heterojunction bipolar transistor (HBT), high frequency MESFET, or other component that utilizes and takes advantage of the physical properties of compound semiconductor materials. A metallic conductor schematically indicated by the line 70 can be formed to electrically couple component 68 and component 56, thus implementing an integrated device that includes at least one component formed in silicon substrate 52 and one device formed in monocrystalline compound semiconductor material layer 66. Although illustrative structure 50 has been described as a structure formed on a silicon substrate 52 and having a barium (or strontium) titanate layer 65 and a gallium arsenide layer 66, similar devices can be fabricated using other substrates, monocrystalline oxide layers and other compound semiconductor layers as described elsewhere in this disclosure.

FIG. 25 illustrates a semiconductor structure 71 in accordance with a further embodiment. Structure 71 includes a monocrystalline semiconductor substrate 73 such as a monocrystalline silicon wafer that includes a region 75 and a region 76. An electrical component schematically illustrated by the dashed line 79 is formed, at least partially, in region 75 using conventional silicon device processing techniques commonly used in the semiconductor industry. Using process steps similar to those described above, a monocrystalline oxide layer 80 and an intermediate amorphous silicon oxide layer 83 are formed overlying region 76 of substrate 73. A template layer 84 and subsequently a monocrystalline semiconductor layer 87 are formed overlying monocrystalline oxide layer 80. In accordance with a further embodiment, an additional monocrystalline oxide layer 88 is formed overlying layer 87 by process steps similar to those used to form layer 80, and an additional monocrystalline semiconductor layer 90 is formed overlying monocrystalline oxide layer 88 by process steps similar to those used to form layer 87. In accordance with one embodiment, at least one of layers 87 and 90 are formed from a compound semiconductor material. Layers 80 and 83 may be subject to an annealing process as described above in connection with FIG. 3 to form a single amorphous accommodating layer.

A semiconductor component generally indicated by a dashed line 92 is formed, at least partially, in monocrystalline semiconductor layer 87. In accordance with one embodiment, semiconductor component 92 may include a field effect transistor having a gate dielectric formed, in part, by monocrystalline oxide layer 88. In addition, monocrystalline semiconductor layer 90 can be used to implement the gate electrode of that field effect transistor. In accordance with one embodiment, monocrystalline semiconductor layer 87 is formed from a group III-V compound and semiconductor component 92 is a radio frequency amplifier that takes advantage of the high mobility characteristic of group III-V component materials. In accordance with yet a further embodiment, an electrical interconnection schematically illustrated by the line 94 electrically interconnects component 79 and component 92. Structure 71 thus integrates components that take advantage of the unique properties of the two monocrystalline semiconductor materials.

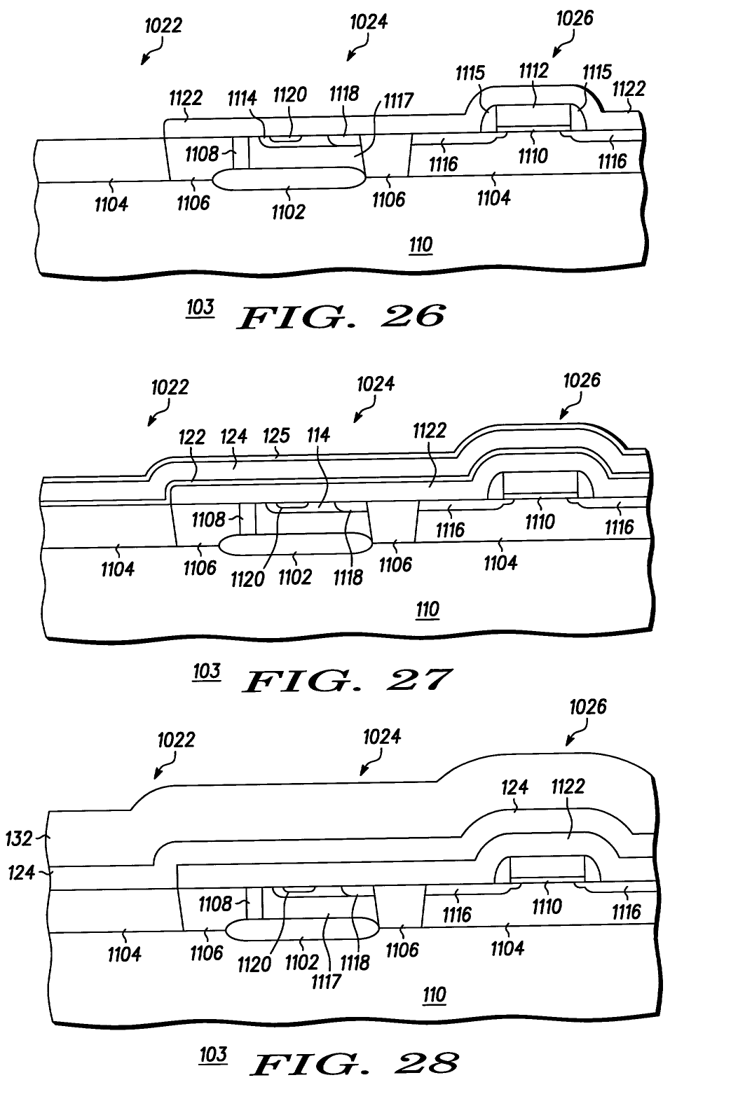

Attention is now directed to a method for forming exemplary portions of illustrative composite semiconductor structures or composite integrated circuits like structure 50 or 71. In particular, the illustrative composite semiconductor structure or integrated circuit 103 shown in FIGS. 26-30 includes a compound semiconductor portion 1022, a bipolar portion 1024, and a MOS portion 1026. In FIG. 26, a p-type doped, monocrystalline silicon substrate 110 is provided having a compound semiconductor portion 1022, a bipolar portion 1024, and an MOS portion 1026. Within bipolar portion 1024, the monocrystalline silicon substrate 110 is doped to form an N⁺ buried region 1102. A lightly p-type doped epitaxial monocrystalline silicon layer 1104 is then formed over the buried region 1102 and the substrate 110. A doping step is then performed to create a lightly n-type doped drift region 1117 above the N⁺ buried region 1102. The doping step converts the dopant type of the lightly p-type epitaxial layer within a section of the bipolar region 1024 to a lightly n-type monocrystalline silicon region. A field isolation region 1106 is then formed between and around the bipolar portion 1024 and the MOS portion 1026. A gate dielectric layer 1110 is formed over a portion of the epitaxial layer 1104 within MOS portion 1026, and the gate electrode 1112 is then formed over the gate dielectric layer 1110. Sidewall spacers 1115 are formed along vertical sides of the gate electrode 1112 and gate dielectric layer 1110.

A p-type dopant is introduced into the drift region 1117 to form an active or intrinsic base region 1114. An n-type, deep collector region 1108 is then formed within the bipolar portion 1024 to allow electrical connection to the buried region 1102. Selective n-type doping is performed to form N⁺ doped regions 1116 and the emitter region 1120. N⁺ doped regions 1116 are formed within layer 1104 along adjacent sides of the gate electrode 1112 and are source, drain, or source/drain regions for the MOS transistor. The N⁺ doped regions 1116 and emitter region 1120 have a doping concentration of at least 1E19 atoms per cubic centimeter to allow ohmic contacts to be formed. A p-type doped region is formed to create the inactive or extrinsic base region 1118 which is a P⁺ doped region (doping concentration of at least 1E19 atoms per cubic centimeter).

In the embodiment described, several processing steps have been performed but are not illustrated or further described, such as the formation of well regions, threshold adjusting implants, channel punchthrough prevention implants, field punchthrough prevention implants, as well as a variety of masking layers. The formation of the device up to this point in the process is performed using conventional steps. As illustrated, a standard N-channel MOS transistor has been formed within the MOS region 1026, and a vertical NPN bipolar transistor has been formed within the bipolar portion 1024. Although illustrated with a NPN bipolar transistor and a N-channel MOS transistor, device structures and circuits in accordance with various embodiment may additionally or alternatively include other electronic devices formed using the silicon substrate. As of this point, no circuitry has been formed within the compound semiconductor portion 1022.

After the silicon devices are formed in regions 1024 and 1026, a protective layer 1122 is formed overlying devices in regions 1024 and 1026 to protect devices in regions 1024 and 1026 from potential damage resulting from device formation in region 1022. Layer 1122 may be formed of, for example, an insulating material such as silicon oxide or silicon nitride.

All of the layers that have been formed during the processing of the bipolar and MOS portions of the integrated, except for epitaxial layer 1104 but including protective layer 1122, circuit are now removed from the surface of compound semiconductor portion 1022. A bare silicon surface is thus provided for the subsequent processing of this portion, for example in the manner set forth above.

An accommodating buffer layer 124 is then formed over the substrate 110 as illustrated in FIG. 27. The accommodating buffer layer will form as a monocrystalline layer over the properly prepared (i.e., having the appropriate template layer) bare silicon surface in portion 1022. The portion of layer 124 that forms over portions 1024 and 1026, however, may be polycrystalline or amorphous because it is formed over a material that is not monocrystalline, and therefore, does not nucleate monocrystalline growth. The accommodating buffer layer 124 typically is a monocrystalline metal oxide or nitride layer and typically has a thickness in a range of approximately 2-100 nanometers. In one particular embodiment, the accommodating buffer layer is approximately 5-15 nm thick. During the formation of the accommodating buffer layer, an amorphous intermediate layer 122 is formed along the uppermost silicon surfaces of the integrated circuit 103. This amorphous intermediate layer 122 typically includes an oxide of silicon and has a thickness and range of approximately 1-5 nm. In one particular embodiment, the thickness is approximately 2 nm. Following the formation of the accommodating buffer layer 124 and the amorphous intermediate layer 122, a template layer 125 is then formed and has a thickness in a range of approximately one to ten monolayers of a material. In one particular embodiment, the material includes titanium-arsenic, strontium-oxygen-arsenic, or other similar materials as previously described with respect to FIGS. 1-5.

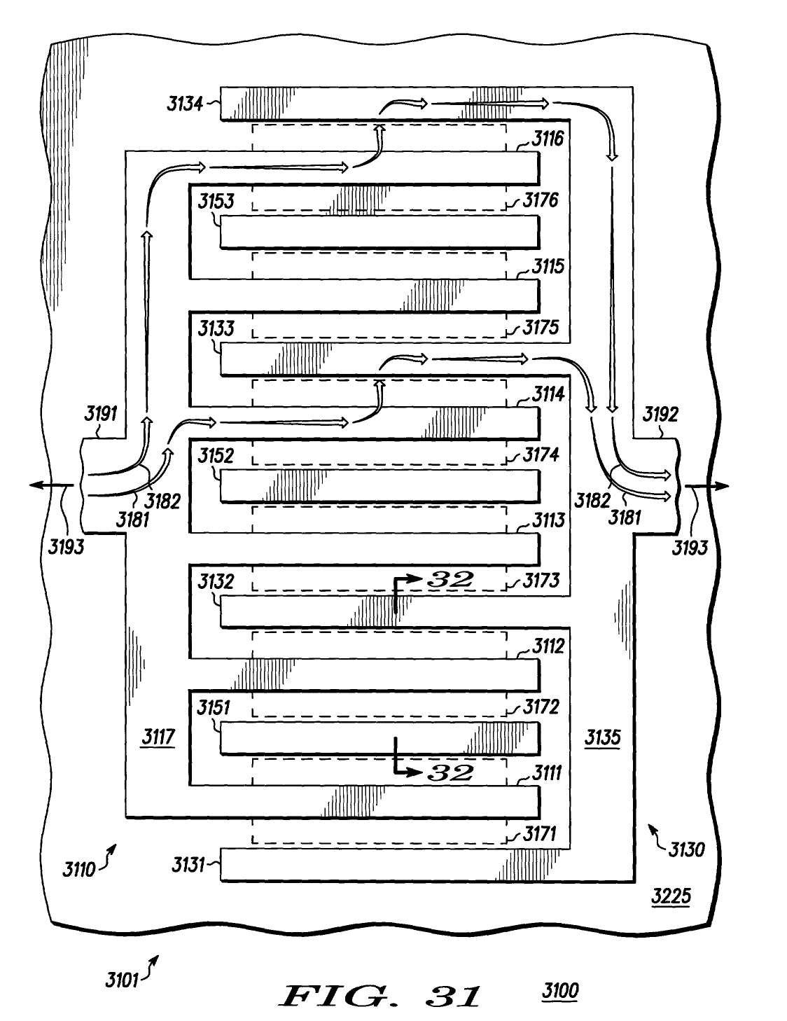

A monocrystalline compound semiconductor layer 132 is then epitaxially grown overlying the monocrystalline portion of accommodating buffer layer 124 as shown in FIG. 28. The portion of layer 132 that is grown over portions of layer 124 that are not monocrystalline may be polycrystalline or amorphous. The monocrystalline compound semiconductor layer can be formed by a number of methods and typically includes a material such as gallium arsenide, aluminum gallium arsenide, indium phosphide, or other compound semiconductor materials as previously mentioned. The thickness of the layer is in a range of approximately 1-5,000 nm, and more preferably 100-2000 nm. Furthermore, additional monocrystalline layers may be formed above layer 132, as discussed in more detail below in connection with FIGS. 31-32.

In this particular embodiment, each of the elements within the template layer are also present in the accommodating buffer layer 124, the monocrystalline compound semiconductor material 132, or both. Therefore, the delineation between the template layer 125 and its two immediately adjacent layers disappears during processing. Therefore, when a transmission electron microscopy (TEM) photograph is taken, an interface between the accommodating buffer layer 124 and the monocrystalline compound semiconductor layer 132 is seen.

After at least a portion of layer 132 is formed in region 1022, layers 122 and 124 may be subject to an annealing process as described above in connection with FIG. 3 to form a single amorphous accommodating layer. If only a portion of layer 132 is formed prior to the anneal process, the remaining portion may be deposited onto structure 103 prior to further processing.

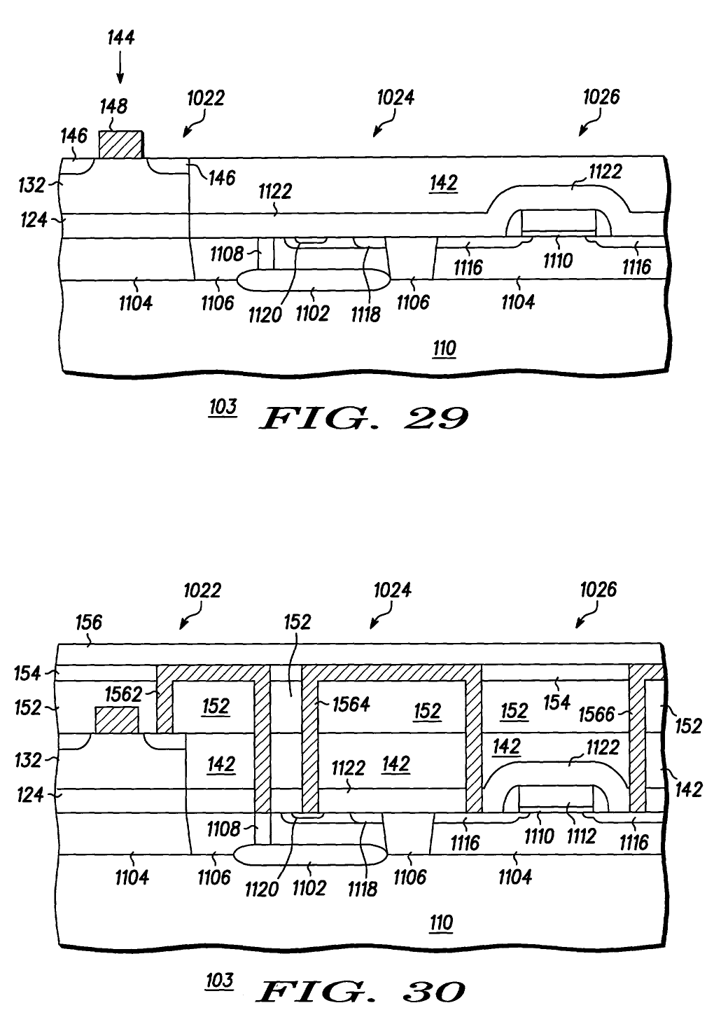

At this point in time, sections of the compound semiconductor layer 132 and the accommodating buffer layer 124 (or of the amorphous accommodating layer if the annealing process described above has been carried out) are removed from portions overlying the bipolar portion 1024 and the MOS portion 1026 as shown in FIG. 29. After the section of the compound semiconductor layer and the accommodating buffer layer 124 are removed, an insulating layer 142 is formed over protective layer 1122. The insulating layer 142 can include a number of materials such as oxides, nitrides, oxynitrides, low-k dielectrics, or the like. As used herein, low-k is a material having a dielectric constant no higher than approximately 3.5. After the insulating layer 142 has been deposited, it is then polished or etched to remove portions of the insulating layer 142 that overlie monocrystalline compound semiconductor layer 132.

A transistor 144 is then formed within the monocrystalline compound semiconductor portion 1022. A gate electrode 148 is then formed on the monocrystalline compound semiconductor layer 132. Doped regions 146 are then formed within the monocrystalline compound semiconductor layer 132. In this embodiment, the transistor 144 is a metal-semiconductor field-effect transistor (MESFET). If the MESFET is an n-type MESFET, the doped regions 146 and at least a portion of monocrystalline compound semiconductor layer 132 are also n-type doped. If a p-type MESFET were to be formed, then the doped regions 146 and at least a portion of monocrystalline compound semiconductor layer 132 would have just the opposite doping type. The heavier doped (N⁺) regions 146 allow ohmic contacts to be made to the monocrystalline compound semiconductor layer 132. At this point in time, the active devices within the integrated circuit have been formed. Although not illustrated in the drawing figures, additional processing steps such as formation of well regions, threshold adjusting implants, channel punchthrough prevention implants, field punchthrough prevention implants, and the like may be performed in accordance with the present invention. This particular embodiment includes an n-type MESFET, a vertical NPN bipolar transistor, and a planar n-channel MOS transistor. Many other types of transistors, including P-channel MOS transistors, p-type vertical bipolar transistors, p-type MESFETs, and combinations of vertical and planar transistors, can be used. Also, other electrical components, such as resistors, capacitors, diodes, and the like, may be formed in one or more of the portions 1022, 1024, and 1026.

Processing continues to form a substantially completed integrated circuit 103 as illustrated in FIG. 30. An insulating layer 152 is formed over the substrate 110. The insulating layer 152 may include an etch-stop or polish-stop region that is not illustrated in FIG. 30. A second insulating layer 154 is then formed over the first insulating layer 152. Portions of layers 154, 152, 142, 124, and 1122 are removed to define contact openings where the devices are to be interconnected. Interconnect trenches are formed within insulating layer 154 to provide the lateral connections between the contacts. As illustrated in FIG. 30, interconnect 1562 connects a source or drain region of the n-type MESFET within portion 1022 to the deep collector region 1108 of the NPN transistor within the bipolar portion 1024. The emitter region 1120 of the NPN transistor is connected to one of the doped regions 1116 of the n-channel MOS transistor within the MOS portion 1026. The other doped region 1116 is electrically connected to other portions of the integrated circuit that are not shown. Similar electrical connections are also formed to couple regions 1118 and 1112 to other regions of the integrated circuit.

A passivation layer 156 is formed over the interconnects 1562, 1564, and 1566 and insulating layer 154. Other electrical connections are made to the transistors as illustrated as well as to other electrical or electronic components within the integrated circuit 103 but are not illustrated in the FIGS. Further, additional insulating layers and interconnects may be formed as necessary to form the proper interconnections between the various components within the integrated circuit 103. Electrical contacts such as, for example, wire bonding pads and flip-chip bumps, can be also be formed, as desired.

As can be seen from the previous embodiment, active devices for both compound semiconductor and Group IV semiconductor materials can be integrated into a single integrated circuit. Because there is some difficulty in incorporating both bipolar transistors and MOS transistors within a same integrated circuit, it may be possible to move some of the components within bipolar portion 1024 into the compound semiconductor portion 1022 or the MOS portion 1026. Therefore, the requirement of special fabricating steps solely used for making a bipolar transistor can be eliminated. Therefore, there would only be a compound semiconductor portion and a MOS portion to the integrated circuit.

The semiconductor structures and processes described hereinabove can be used to form large periphery transistors with more even or balanced temperature and current distribution across the transistors. This improved temperature and current distribution extends the operating lifetimes and increases reliability for the transistors. The semiconductor structure and process described hereinabove can also be used to simultaneously form the large periphery transistors with reduced phased imbalances across the transistors. This improved phase balancing increases the output power for the transistors.

An improved transistor can be formed by selectively doping predetermined portions of the monocrystalline compound semiconductor material in the semiconductor structure. In some embodiments, the monocrystalline perovskite oxide material in the semiconductor structure can also be selectively doped. The selective doping scheme can provide a low cost, high performance transistor having both low noise and high output power. One skilled in the art will understand that a plurality of such transistors can also be formed in the semiconductor structure to form an integrated circuit in a single semiconductor chip.

The transistors described herein are typically field effect transistors (FETs) such as, for example, MESFETs, or high electron mobility transistors (HEMTs) such as, for example, pseudomorphic HEMTs or metamorphic HEMTs. One skilled in the art, however, will understand that the concepts disclosed herein can also be applied to bipolar transistors such as, for example, HBTs.

In general, the selective doping scheme involves adjusting the doping levels in the monocrystalline compound semiconductor material such that the conductivity level within different active regions of a transistor are different under substantially identical bias conditions. If the transistors are FETs and/or HEMTs, then the active regions are the channel regions in the FETs and/or HEMTs. If the transistors are bipolar transistors, then the active regions are the base regions in the bipolar transistors.

The different conductivity levels of the different active regions can change the temperature across the transistor such that the temperature distribution across the transistor is more even or balanced compared to the prior art transistors. Therefore, the different conductivity levels of the different active regions can substantially eliminate, or at least reduce, a temperature imbalance between the active regions compared to a similar transistor having active regions with substantially identical conductivity levels. Accordingly, the transistor can have a longer operating lifetime and increased reliability.

The different conductivity levels of the different active regions can also change the current levels across the transistor such that the current distribution across the transistor is also more even or balanced compared to the prior art transistors. Therefore, the different conductivity levels of the different active regions can substantially eliminate, or at least reduce, a current imbalance between the active regions compared to a similar transistor having active regions with substantially identical conductivity levels. Accordingly, the transistor can have a longer operating lifetime and improved reliability.

The different conductivity levels of the different active regions can further change the electrical or transmission lengths of the various signal paths from the input of the transistor to the output of the transistor such that all signal paths have the same effective transmission length. By adjusting all of the effective transmission lengths throughout the transistor to be the same, all signals transmitted through the transistor will have the same phase regardless of which signal path is used. Accordingly, the different conductivity levels of the different active regions can substantially eliminate, or at least reduce, a phase imbalance in the transistor compared to a similar transistor having active regions with substantially identical conductivity levels. Therefore, the transistor with the different conductivity levels in different active regions can have an increased output power.

Although the concepts presented herein are described with respect to transistors, one skilled in the art will understand that these concepts can also be applied to other active semiconductor devices such as, for example, diodes. Additionally, one skilled in the art will understand that more than one of such active devices can be formed in a single semiconductor structure. Furthermore, such active devices can be formed in semiconductor materials and/or substrates other than the semiconductor materials and substrates described herein.

FIG. 31 illustrates schematically a top view of an embodiment of a semiconductor structure 3100, and FIG. 32 illustrates schematically a partial cross-sectional view of semiconductor structure 3100 taken along a section line 31-31 in FIG. 31. As explained hereinafter, semiconductor structure 3100 has selective doping in at least some of its layers. Semiconductor structure 3100 comprises a composite substrate is similar to that described earlier. As an example, the composite substrate can include at least a monocrystalline silicon substrate 3210, an amorphous oxide material 3215 overlying monocrystalline silicon substrate 3210, a monocrystalline perovskite oxide material 3220 overlying amorphous oxide material 3215, and a monocrystalline compound semiconductor material 3225 overlying the monocrystalline perovskite oxide material 3220. As explained hereinafter, monocrystalline compound semiconductor material 3225 can represent a single monocrystalline compound semiconductor layer or a plurality of monocrystalline compound semiconductor layers.

Semiconductor structure 3100 also comprises a transistor 3101 located in and over monocrystalline compound semiconductor material 3225. If monocrystalline compound semiconductor material 3225 represents a single monocrystalline compound semiconductor layer, then transistor 3101 can be, for example, a MESFET. If monocrystalline compound semiconductor material 3225 represents a plurality of monocrystalline compound semiconductor layers, then transistor 3101 can be, for example, a HEMT or an HBT. In the embodiment illustrated in FIGS. 31 and 32, transistor 3101 is a FET or HEMT.

Transistor 3101 comprises gate, source, and drain electrodes overlying gate, source, and drain regions, respectively. The specific number, shape, and size of the electrodes and regions within transistor 3101 can be altered from the number described herein depending upon the desired electrical performance of transistor 3101.

In particular, transistor 3101 comprises a gate terminal 3110 located over monocrystalline compound semiconductor material 3225. Gate terminal 3110 comprises gate fingers or gate electrodes 3111, 3112, 3113, 3114, 3115, and 3116. Gate terminal 3110 also comprises a gate bus 3117 electrically and physically coupled to gate electrodes 3111, 3112, 3113, 3114, 3115, and 3116. An input 3191 for transistor 3101 is located at and coupled to gate bus 3117.

Transistor 3101 also comprises a drain terminal 3130 located over monocrystalline compound semiconductor material 3225. Drain terminal 3130 comprises drain fingers or drain electrodes 3131, 3132, 3133, and 3134. Drain terminal 3130 also comprises a drain bus 3135 electrically and physically coupled to drain electrodes 3131, 3132, 3133, and 3134. An output 3192 for transistor 3101 is located at and coupled to drain bus 3135.

Transistor 3101 further comprises a source terminal (partially shown in FIGS. 31 and 32) located over monocrystalline compound semiconductor material 3225. The source terminal comprises source fingers or source electrodes 3151, 3152, and 3153. The source terminal also comprises a source bus (not shown in FIG. 31 or 32) electrically and physically coupled to source electrodes 3151, 3152, and 3153. As an example, the source bus can be formed from a second metal layer not illustrated in FIGS. 31 or 32 to simplify the explanation of transistor 3101.

Gate electrodes 3111, 3112, 3113, 3114, 3115, and 3116 are interdigitated between immediately adjacent ones of drain electrodes 3131, 3132, 3133, and 3134 and source electrodes 3151, 3152, and 3153. In particular, gate electrode 3111 is located between drain electrode 3131 and source electrode 3151, and gate electrode 3112 is located between source electrode 3151 and drain electrode 3132. Additionally, gate electrode 3113 is located between drain electrode 3132 and source electrode 3152, and gate electrode 3114 is located between source electrode 3152 and drain electrode 3133. Moreover, gate electrode 3115 is located between drain electrode 3133 and source electrode 3153, and gate electrode 3116 is located between source electrode 3153 and drain electrode 3134.

Transistor 3101 also comprises drain regions located in monocrystalline compound semiconductor material 3225 and located at least underneath drain electrodes 3131, 3132, 3133, and 3134. As an example, in FIG. 32, a drain region 3232 is located in monocrystalline compound semiconductor material 3225 and underneath drain electrode 3132. Transistor 3101 further comprises source regions located in monocrystalline compound semiconductor material 3225 and located at least underneath source electrodes 3151, 3152, and 3153. As an example, in FIG. 32, a source region 3251 is located in monocrystalline compound semiconductor material 3225 and underneath source electrode 3151.

Transistor 3101 still further comprises channel regions or active regions 3171, 3172, 3173, 3174, 3175, and 3176. Active regions 3171, 3172, 3173, 3174, 3175, and 3176 are located in monocrystalline compound semiconductor material 3225 and are also located at least underneath gate electrodes 3111, 3112, 3113, 3114, 3115, and 3116. Active region 3172 is located between active regions 3171 and 3173; active region 3173 is located between active regions 3172 and 3174; active region 3174 is located between active regions 3173 and 3175; and active region 3175 is located between active region 3174 and 3176. Active regions 3171, 3172, 3173, 3174, 3175, and 3176 are interdigitated between immediately adjacent ones of the drain regions and the source regions. As an example, in FIG. 32, active region 3172 is located between source region 3251 and drain region 3232. Active regions 3171, 3172, 3173, 3174, 3175, and 3176 couple together input 3191 of transistor 3101 and output 3192 of transistor 3101.

Active regions 3171, 3172, 3173, 3174, 3175, and 3176 have different conductivity levels under substantially identical bias conditions. These different conductivity levels can be achieved under the substantially identical bias conditions by adjusting the doping concentrations within active regions 3171, 3172, 3173, 3174, 3175, and 3176 and/or by adjusting the doping concentrations of one or more supply layers located adjacent to active regions 3171, 3172, 3173, 3174, 3175, and 3176. An example of a supply layer is referred to as a delta-doped layer. The middle or central ones of active regions 3171, 3172, 3173, 3174, 3175, and 3176 can be designed to have lower conductivity levels than the outer ones of active regions 3171, 3172, 3173, 3174, 3175, and 3176. In the preferred embodiment, the different conductivity levels of active regions 3171, 3172, 3173, 3174, 3175, and 3176 are symmetric about a geometrically centered axis 3193 for transistor 3101.

As an example, active regions 3171, 3172, 3175, and 3176 can have higher conductivity levels than active regions 3172 and 3173 when active regions 3171, 3172, 3173, 3174, 3175, and 3176 are all biased under substantially identical conditions. In one embodiment of this example, the conductivity levels of active regions 3171, 3172, 3175, and 3176 can be approximately equal to each other, and the conductivity levels of active regions 3173 and 3174 can be approximately equal to each other.

As a different example, active regions 3171 and 3176 can have higher conductivity levels than active regions 3172 and 3175, and active regions 3172 and 3175 can have higher conductivity levels than active regions 3173 and 3174 when active regions 3171, 3172, 3173, 3174, 3175, and 3176 are all biased under substantially identical conditions. In one embodiment of this different example, the conductivity level of active region 3171 can be approximately equal to the conductivity level of active region 3176; the conductivity level of active region 3172 can be approximately equal to the conductivity level of active region 3175; and the conductivity level of active region 3173 can be approximately equal to the conductivity level of active region 3174.

A first actual transmission length extends from input 3191 of transistor 3101 through active region 3171 to output 3192 of transistor 3101, and a second actual transmission length extends from input 3191 of transistor 3101 through active region 3172 to output 3192 of transistor 3101. Additionally, a third actual transmission length extends from input 3191 through active region 3173 to output 3192, and a fourth actual transmission length extends from input 3191 through active region 3174 to output 3192. Furthermore, a fifth actual transmission length extends from input 3191 through active region 3175 to output 3192, and a sixth actual transmission length extends from input 3191 through active region 3176 to output 3192. An example of the fourth actual transmission length is represented by a dotted line 3181, and an example of the sixth actual transmission length is represented by a dashed line 3182.

The first and sixth actual transmission lengths are longer than the second and fifth actual transmission lengths, and the second and fifth actual transmission lengths are longer than the third and fourth actual transmission lengths. In the preferred embodiment, the first and sixth actual transmission lengths are the same distance; the second and fifth actual transmission lengths are the same distance; and the third and fourth actual transmission lengths are the same distance.

The aforementioned different conductivity levels of active regions 3171, 3172, 3173, 3174, 3175, and 3176 provide a first effective transmission length for the first actual transmission length, a second effective transmission length for the second actual transmission length, a third effective transmission length for the third actual transmission length, a fourth effective transmission length for the fourth actual transmission length, a fifth effective transmission length for the fifth actual transmission length, and a sixth effective transmission length for the sixth actual transmission length. The first, second, third, fourth, fifth, and sixth effective transmission lengths are approximately equal with each other.

The effective transmission lengths are believed to be equalized as follows. First the conductivity levels of active regions 3171, 3172, 3173, 3174, 3175, and 3176 are varied to modify the size of the depletion regions within active regions 3171, 3172, 3173, 3174, 3175, and 3176. The modified depletion regions change the propagation constants of the transmission medium or monocrystalline compound semiconductor material 3225 in which active regions 3171, 3172, 3173, 3174, 3175, and 3176 are located. The changed propagation constants, in turn, alter the phase velocity in the transmission medium, and the altered phase velocity modifies or changes the actual transmission length to the effective transmission length. The balancing or equalizing of the effective transmission lengths balances the phase of the various signals conducted through active regions 3171, 3172, 3173, 3174, 3175, and 3176 of transistor 3101 and recombined at output 3192 of transistor 3101.

One skilled in the art will understand that the aforementioned different conductivity levels of active regions 3171, 3172, 3173, 3174, 3175, and 3176 also provide a more even or balanced temperature distribution across transistor 3101. One skilled in the art will also understand that the aforementioned different conductivity levels of active regions 3171, 3172, 3173, 3174, 3175, and 3176 further provide a more even or balanced temperature distribution across transistor 3101.

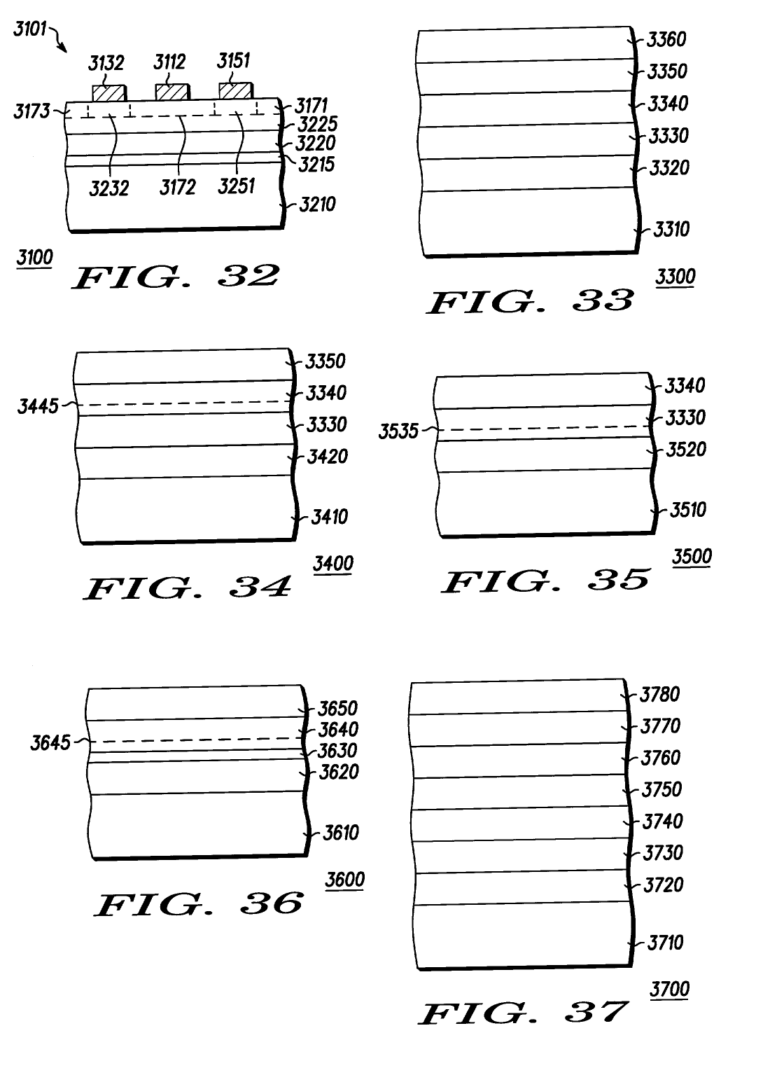

FIG. 33 illustrates schematically a cross-sectional view of an embodiment of a composite monocrystalline compound semiconductor material 3300. As an example, monocrystalline compound semiconductor material 3300 can be an embodiment of monocrystalline compound semiconductor material 3225 in FIGS. 31 and 32. Monocrystalline compound semiconductor material 3300 in FIG. 33 can include an indium aluminum gallium arsenide (InAlGaAs) buffer layer 3310 overlying monocrystalline perovskite oxide material 3220 (FIG. 32) and an InAlGaAs layer 3320 overlying InAlGaAs buffer layer 3310. Monocrystalline compound semiconductor material 3300 can further include an indium gallium arsenide (InGaAs) layer 3330 overlying InAlGaAs layer 3320, a barium strontium zirconate ((BaSr)ZrO₃) layer 3340 overlying InGaAs layer 3330, a strontium zirconium titanate (Sr(ZrTi)O₃) layer 3350 overlying (BaSr)ZrO₃ layer 3340, and an InAlGaAs layer 3360 overlying Sr(ZrTi)O₃ layer 3350.

One skilled in the art will understand that when InAlGaAs layer 3360 represents a heavily doped ohmic layer, then a portion of InAlGaAs layer 3360 is removed to expose a portion of Sr(ZrTi)O₃ layer 3350 such that the gate electrodes of the transistor are formed over Sr(ZrTi)O₃ layer 3350 and not over InAlGaAs layer 3360. In a different embodiment, a portion of Sr(ZrTi)O₃ layer 3350 can also be removed to expose a portion of (BaSr)ZrO₃ layer 3340 on which the gate electrodes can be formed.

In another embodiment of monocrystalline compound semiconductor material 3300, an additional monocrystalline perovskite oxide material can be located between (Sr(ZrTi)O₃) layer 3350 and (BaSr)ZrO₃ layer 3340. In a further embodiment of monocrystalline compound semiconductor material 3300, an additional monocrystalline perovskite oxide material can be located between (BaSr)ZrO₃ layer 3340 and InGaAs layer 3330. In yet another embodiment of monocrystalline compound semiconductor material 3300, both of these two additional monocrystalline perovskite oxide materials can be used.

As a variation to these three embodiments, any or all of the monocrystalline perovskite oxide materials including monocrystalline perovskite oxide material 3220 in FIG. 32 can be doped. For example, each of the monocrystalline perovskite oxide materials can be doped with niobium (Nb). When doped, the monocrystalline perovskite oxide materials preferably have less than five percent niobium. When the monocrystalline perovskite oxide material comprises strontium titanate (SrTiO₃), this doped material can be expressed as Nb:SrTiO₃.

If desired, the dielectric constant of the monocrystalline perovskite oxide materials can be changed as well. For example, the addition of approximately one percent of aluminum to the monocrystalline perovskite oxide material can change the dielectric constant of the monocrystalline perovskite oxide material by approximately five percent.

FIG. 34 illustrates schematically a cross-sectional view of an embodiment of a composite monocrystalline compound semiconductor material 3400. As an example, monocrystalline compound semiconductor material 3400 can be an embodiment of monocrystalline compound semiconductor material 3225 in FIGS. 31 and 32. As illustrated in FIG. 34, monocrystalline compound semiconductor material 3400 comprises a layer 3410, a layer 3420 overlying layer 3410, a layer 3430 overlying layer 3420, a layer 3440 overlying layer 3430, and a layer 3450 overlying layer 3440.

Layer 3440 comprises a delta-doped layer 3445, represented by a dashed line. A portion of layer 3440 located below delta doped layer 3445 can be referred to as a spacer layer, and a portion of layer 3440 located above delta doped layer 3445 can be referred to as a barrier layer. A portion of layer 3450 can be removed to expose a portion of layer 3440 such that the gate electrodes of the transistor are formed over layer 3440 and not over layer 3450.

In a first embodiment of monocrystalline compound semiconductor material 3400, layer 3410 can represent a first buffer layer comprised of undoped gallium arsenide (GaAs), and layer 3420 can represent a second buffer layer comprised of undoped aluminum gallium arsenide (AlGaAs). Additionally, layer 3430 can represent an active or channel layer comprised of undoped gallium arsenide, and layer 3440 can represent a spacer and barrier layer comprised of undoped AlGaAs, preferably Al_{0.24}GaAs. Delta doped layer 3445 can be comprised of silicon and can have a doping concentration of approximately 5×10¹² atoms per centimeter cubed (cm⁻³). Layer 3450 can represent an ohmic cap layer comprised of silicon (Si) doped GaAs. As an example, layer 3450 can have a doping concentration of approximately 5×10¹⁸ cm⁻³.

In this first embodiment, layers 3410, 3420, 3430, 3440, and 3450 can have thicknesses of approximately five hundred nanometers (nm), greater than approximately thirty nm, approximately twenty-five nm, approximately thirty nm, and approximately forty nm, respectively. Layer 3440 can have approximately three nm below delta doped layer 3445 and approximately twenty-seven nm above delta doped layer 3445. In this first embodiment, transistor 3101 in FIGS. 31 and 32 can be a HEMT. As a variation to this first embodiment, monocrystalline compound semiconductor material 3400 can additionally include a GaAs layer between layer 3410 and monocrystalline perovskite oxide material 3220 (FIG. 32).

In a second embodiment of monocrystalline compound semiconductor material 3400, layer 3410 can represent a first buffer layer comprised of undoped GaAs, and layer 3420 can represent a second buffer layer comprised of undoped AlGaAs. Additionally, layer 3430 can represent an active or channel layer comprised of undoped InGaAs, preferably In_{0.19}GaAs, and layer 3440 can represent a spacer and barrier layer comprised of undoped AlGaAs, preferably Al_{0.24}GaAs. Delta doped layer 3445 can be comprised of silicon and can have a doping concentration of approximately 5×10¹² cm⁻³. Layer 3450 can represent an ohmic cap layer comprised of Si doped GaAs. As an example, layer 3450 can have a doping concentration of greater than approximately 5×10¹⁸ cm⁻³.

In this second embodiment, layers 3410, 3420, 3430, 3140, and 3150 can have thicknesses of approximately five hundred nm, greater than approximately thirty nm, approximately fifteen nm, approximately thirty nm, and approximately fifty nm, respectively. Layer 3440 can have approximately three nm below delta doped layer 3445 and approximately twenty-seven nm above delta doped layer 3445. Also in this second embodiment, transistor 3101 in FIGS. 31 and 32 can be a pseudomorphic HEMT. In an alternative embodiment, monocrystalline compound semiconductor material 3400 can additionally include a GaAs layer between layer 3410 and monocrystalline perovskite oxide material 3220 (FIG. 32).

FIG. 35 illustrates schematically a cross-sectional view of an embodiment of a composite monocrystalline compound semiconductor material 3500. As an example, monocrystalline compound semiconductor material 3500 can be an embodiment of monocrystalline compound semiconductor material 3225 in FIGS. 31 and 32. As illustrated in FIG. 35, monocrystalline compound semiconductor material 3500 comprises a layer 3510, a layer 3520 overlying layer 3510, a layer 3530 overlying layer 3520, and a layer 3540 overlying layer 3530.

Layer 3530 comprises a delta-doped layer 3535, represented by a dashed line. A portion of layer 3530 located below delta doped layer 3535 can be referred to as a spacer layer, and a portion of layer 3530 located above delta doped layer 3535 can be referred to as a barrier layer. A portion of layer 3540 can be removed to expose a portion of layer 3530 such that the gate electrodes of the transistor are formed over layer 3530 and not over layer 3540.

Layer 3510 can represent a buffer layer comprised of undoped aluminum indium arsenide (AlInAs), preferably Al_{0.52}InAs, and layer 3520 can represent an active or channel layer comprised of undoped InGaAs, preferably In_{0.53}GaAs. Additionally, layer 3530 can represent a spacer and barrier layer and can be comprised of undoped AlInAs, preferably, Al_{0.52}InAs. Delta doped layer 3535 can be comprised of silicon and can have a doping concentration of approximately 5×10¹² cm⁻³. Layer 3540 can represent an ohmic cap layer comprised of Si doped InGaAs, preferably In_{0.53}GaAs. As an example, layer 3540 can have a doping concentration of greater than approximately 5×10¹⁸ cm⁻³.

Layers 3510, 3520, 3530, and 3540 can have thicknesses of greater than approximately five hundred nm, approximately twenty-five nm, approximately twenty-two nm, and approximately ten nm, respectively. Layer 3530 can have approximately two nm below delta doped layer 3535 and approximately twenty nm above delta doped layer 3535. In this embodiment of monocrystalline compound semiconductor material 3500, transistor 3101 in FIGS. 31 and 32 can be a HEMT. As a variation to this embodiment, monocrystalline compound semiconductor material 3500 can additionally include an indium phosphide (InP) layer between layer 3410 and monocrystalline perovskite oxide material 3220 (FIG. 32).

FIG. 36 illustrates schematically a cross-sectional view of an embodiment of a composite monocrystalline compound semiconductor material 3600. As an example, monocrystalline compound semiconductor material 3600 can be an embodiment of monocrystalline compound semiconductor material 3225 in FIGS. 31 and 32. As illustrated in FIG. 36, monocrystalline compound semiconductor material 3600 comprises a layer 3610, a layer 3620 overlying layer 3610, a layer 3630 overlying layer 3620, a layer 3640 overlying layer 3630, and a layer 3650 overlying layer 3640.

Layer 3640 comprises a delta-doped layer 3645, represented by a dashed line. A portion of layer 3640 located below delta doped layer 3645 can be referred to as a spacer layer, and a portion of layer 3640 located above delta doped layer 3645 can be referred to as a barrier layer. A portion of layer 3650 can be removed to expose a portion of layer 3640 such that the gate electrodes of the transistor are formed over layer 3640 and not over layer 3650.

Layer 3610 can represent a graded buffer layer comprised of AlGaAs graded to AlInAs, and layer 3620 can represent an ungraded buffer layer comprised of undoped AlInAs, preferably Al_{0.52}InAs. Additionally, layer 3630 can represent an active or channel layer comprised of undoped InGaAs, preferably In_{0.53}GaAs. Furthermore, layer 3640 can represent a spacer and barrier layer comprised of undoped AlInAs, preferably, Al_{0.52}InAs. Delta doped layer 3645 can be comprised of silicon and can have a doping concentration of approximately 5×10¹² cm⁻³. Layer 3650 can represent an ohmic cap layer comprised of Si doped InGaAs, preferably In_{0.53}GaAs. As an example, layer 3650 can have a doping concentration of greater than approximately 5×10¹⁸ cm⁻³.

Layers 3610, 3620, 3630, 3140, and 3650 can have thicknesses of approximately one micrometer, greater than approximately five hundred nm, approximately twenty-five nm, approximately twenty-two nm, and approximately ten nm, respectively. In this embodiment of monocrystalline compound semiconductor material 3600, transistor 3101 in FIGS. 31 and 32 can be a metamorphic HEMT. As a variation to this embodiment, monocrystalline compound semiconductor material 3600 can additionally include a GaAs layer between layer 3410 and monocrystalline perovskite oxide material 3220 (FIG. 32).

FIG. 37 illustrates schematically a cross-sectional view of an embodiment of a composite monocrystalline compound semiconductor material 3700. As an example, monocrystalline compound semiconductor material 3700 can be an embodiment of monocrystalline compound semiconductor material 3225 in FIGS. 31 and 32.

As illustrated in FIG. 37, monocrystalline compound semiconductor material 3700 comprises a layer 3710, a layer 3720 overlying layer 3710, a layer 3730 overlying layer 3720, a layer 3740 overlying layer 3730, a layer 3750 overlying layer 3740, a layer 3760 overlying layer 3750, a layer 3770 overlying layer 3760, and a layer 3780 overlying layer 3770. In this embodiment of monocrystalline compound semiconductor material 3700, transistor 3101 in FIGS. 31 and 32 can be a HBT.

Layer 3710 can represent subcollector layer comprised of Si doped GaAs, and layer 3720 can represent a collector layer comprised of Si doped GaAs. As an example, layers 3710 and 3720 can have doping concentrations of greater than approximately 5×10¹⁸ cm⁻³ and approximately 5×10¹⁶ cm⁻³, respectively. Additionally, layer 3730 can represent a base layer comprised of carbon doped GaAs, and layer 3740 can represent a graded layer comprised of Si doped GaAs graded to Si doped AlGaAs, preferably Al_{0.25}GaAs. As an example, layers 3730 and 3740 can have doping concentrations of approximately 1×10¹⁹ cm⁻³ and approximately 5×10¹⁷ cm⁻³, respectively.

Furthermore, layer 3750 can represent an emitter layer comprised of Si doped AlGaAs, preferably Al_{0.25}GaAs, and layer 3760 can represent a first ohmic cap layer comprised of Si doped GaAs. As an example layers 3750 and 3760 can have doping concentrations of approximately 5×10¹⁷ cm⁻³ and greater than approximately 5×10¹⁸ cm⁻³, respectively. Moreover, layer 3770 can represent a graded layer comprised of Si doped GaAs to Si doped InGaAs, preferably In_{0.5}GaAs, and layer 3780 can represent a second ohmic cap layer comprised of Si doped InGaAs, preferably In_{0.5}GaAs. As an example, layer 3770 can have a doping concentration of greater than approximately 5×10¹⁸ cm⁻³, and layer 3780 can have a doping concentration of greater than approximately 5×10¹⁸ cm⁻³.

Layers 3710, 3720, 3730, 3140, 3750, 3760, 3770, and 3780 can have thicknesses of approximately three hundred nm, approximately seven hundred nm, approximately one hundred nm, approximately twenty nm, approximately seventy nm, approximately one hundred nm, approximately forty nm, and approximately thirty nm, respectively. As a variation to this embodiment, monocrystalline compound semiconductor material 3700 can additionally include a GaAs layer between layer 3410 and monocrystalline perovskite oxide material 3220 (FIG. 32).

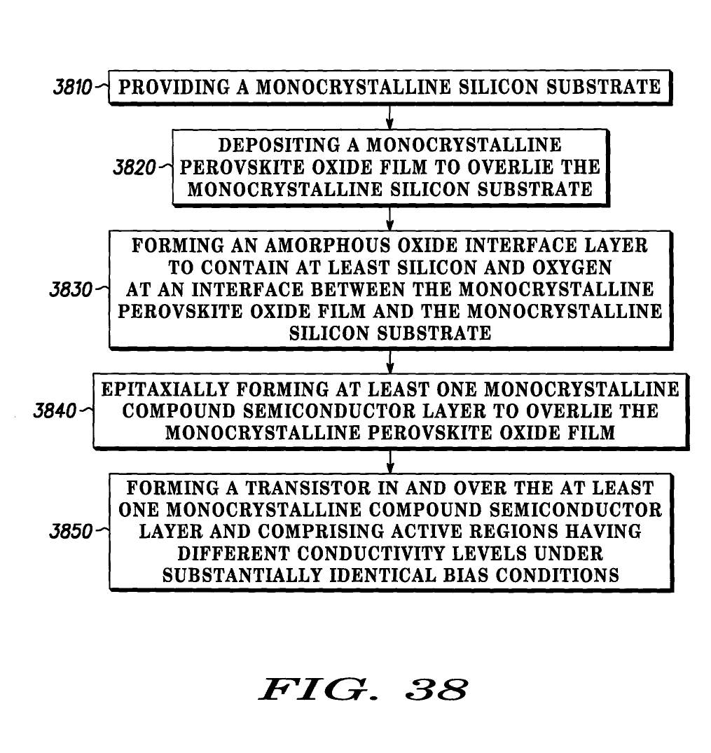

FIG. 38 illustrates a flow chart 3800 of an embodiment of a process for fabricating a semiconductor structure with selective doping. At a step 3810 of flow chart 3800, a monocrystalline silicon substrate is provided. Next, at a step 3820, a monocrystalline perovskite oxide film is deposited to overlie the monocrystalline silicon substrate. The film has a thickness less than a thickness of the material that would result in strain-induced defects. Then, at a step 3830, an amorphous oxide interface layer is formed to contain at least silicon and oxygen at an interface between the monocrystalline perovskite oxide film and the monocrystalline silicon substrate. Subsequently, at a step 3840, at least one monocrystalline compound semiconductor layer is epitaxially formed to overlie the monocrystalline perovskite oxide film. Next, at a step 3850, a transistor is formed in and over the at least one monocrystalline compound semiconductor layer and comprises active regions having different conductivity levels under substantially identical bias conditions.

The details of the steps in flow chart 3800 have already been described, and variations of the steps in flow chart 3800 can include, but are not limited to, the following examples. For instance, the fabrication process can further include (1) selectively doping first portions of the at least one monocrystalline compound semiconductor layer with a first doping concentration and (2) selectively doping second portions of the at least one monocrystalline compound semiconductor layer with a second doping concentration. At least portions of the first and second portions of the at least one monocrystalline compound semiconductor layer form the active regions for the transistor.

The two selectively doping steps can occur while epitaxially forming the at least one monocrystalline compound semiconductor layer. As an example, a selective epitaxial growth process can be used to epitaxially form a portion of a monocrystalline compound semiconductor layer that is doped in-situ to a first doping concentration. Then, another selective epitaxial growth process can be used to epitaxially form a different portion of the monocrystalline compound semiconductor layer that is doped in-situ to a second doping concentration. The multiple selective epitaxial growth processes can also be used to epitaxially form a portion of the monocrystalline compound semiconductor layer that is not doped in-situ.

In a different embodiment, the two selectively doping steps can occur after epitaxially forming the at least one monocrystalline compound semiconductor layer. As an example, after one or several of the monocrystalline compound semiconductor layers is epitaxially grown, then the monocrystalline compound semiconductor layer(s) can be selectively implanted and/or selectively diffused with one or more dopants.

When a delta-doped layer is used in the at least one monocrystalline compound semiconductor layer of step 3850, other selective doping techniques can also be used.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A semiconductor structure with selective doping comprising:
a monocrystalline silicon substrate;
an amorphous oxide material overlying the monocrystalline silicon substrate;
a monocrystalline perovskite oxide material overlying the amorphous oxide material;
at least one monocrystalline compound semiconductor material overlying the monocrystalline perovskite oxide material; and
a transistor in the at least one monocrystalline compound semiconductor material and comprising active regions having different conductivity levels under substantially identical bias conditions.

2. The semiconductor structure of claim 1 wherein:
the different conductivity levels reduce a phase imbalance in the transistor compared to a similar transistor having active regions with substantially identical conductivity levels.

3. The semiconductor structure of claim 1 wherein:
the different conductivity levels reduce a temperature imbalance between the active regions compared to a similar transistor having active regions with substantially identical conductivity levels.

4. The semiconductor structure of claim 1 wherein:
the different conductivity levels reduce a current imbalance between the active regions compared to a similar transistor having active regions with substantially identical conductivity levels.

5. The semiconductor structure of claim 1 wherein:
the transistor is a metal-semiconductor field effect transistor.

6. The semiconductor structure of claim 1 wherein:
the transistor is a high electron mobility transistor.

7. The semiconductor structure of claim 1 wherein:
the transistor is a heterojunction bipolar transistor.

8. The semiconductor structure of claim 1 wherein:
the transistor further comprises:
a first one of the active regions in the at least one monocrystalline compound semiconductor material and having a first conductivity level;
a second one of the active regions in the at least one monocrystalline compound semiconductor material and having a second conductivity level; and
a third one of the active regions in the at least one monocrystalline compound semiconductor material, between the first and second ones of the active regions, and having a third conductivity level less than the first and second conductivity levels.

9. The semiconductor structure of claim 8 wherein:
the transistor further comprises:
an input; and
an output;
a first actual transmission length extends from the input of the transistor through the first one of the active regions to the output of the transistor;
a second actual transmission length extends from the input of the transistor through the second one of the active regions to the output of the transistor;
a third actual transmission length extends from the input of the transistor through the third one of the active regions to the output of the transistor and is shorter than the first and second actual transmission lengths; and
the first, second, and third conductivity levels provide:
a first effective transmission length along the first actual transmission length;
a second effective transmission length along the second actual transmission length; and
a third effective transmission length along the third actual transmission length and approximately equal to the first and second effective transmission lengths.

10. The semiconductor structure of claim 8 wherein:
the first, second, and third conductivity levels substantially eliminate a phase imbalance in the transistor compared to a similar transistor having first, second, and third active regions with substantially identical conductivity levels.

11. The semiconductor structure of claim 8 wherein:
the first, second, and third conductivity levels substantially eliminate a temperature imbalance and a current imbalance between the active regions compared to a similar transistor having first, second, and third active regions with substantially identical conductivity levels.

12. The semiconductor structure of claim 8 wherein:
the second conductivity level is approximately equal to the first conductivity level.

13. The semiconductor structure of claim 8 wherein:
the transistor further comprises:
a fourth one of the active regions in the at least one monocrystalline compound semiconductor material, between the first and third ones of the active regions, and having a fourth conductivity level less than the first and second conductivity levels.

14. The semiconductor structure of claim 13 wherein:
the fourth conductivity level is approximately equal to the third conductivity level.

15. The semiconductor structure of claim 13 wherein:
the transistor further comprises:
a first drain region adjacent to the first one of the active regions;
a second drain region between the third and fourth ones of the active regions;
a third drain region adjacent to the second one of the active regions;
a first source region between the first and fourth one of the active regions; and
a second source region between the second and third ones of the active regions.

16. The semiconductor structure of claim 8 wherein:
the transistor further comprises:
a first gate electrode over the first one of the active regions;
a second gate electrode over the second one of the active regions; and
a third gate electrode over the third one of the active regions.

17. The semiconductor structure of claim 16 wherein:
the transistor further comprises:
a gate bus electrically coupled to the first, second, and third gate electrodes.

18. The semiconductor structure of claim 16 wherein:
the transistor further comprises:
a fourth one of the active regions in the at least one monocrystalline compound semiconductor material, between the first and third ones of the active regions, and having a fourth conductivity level less than the first and second conductivity levels;
a fourth gate electrode over the fourth one of the active regions;
a first drain electrode adjacent to the first gate electrode;
a second drain electrode between the third and fourth gate electrodes;
a third drain electrode adjacent to the second gate electrode;
a first source electrode between the first and fourth gate electrodes; and
a second source electrode between the second and third gate electrodes.

19. The semiconductor structure of claim 1 wherein:
the at least one monocrystalline compound semiconductor material comprises:
an InGaAs layer overlying the monocrystalline perovskite oxide material;
a (BaSr)ZrO₃ layer overlying the InGaAs layer;
a Sr(ZrTi)O₃ layer overlying the (BaSr)ZrO₃ layer; and
an InAlGaAs layer overlying the Sr(ZrTi)O₃ layer.

20. The semiconductor structure of claim 19 further comprising:
a second monocrystalline perovskite oxide material between the Sr(ZrTi)O₃ layer and the (BaSr)ZrO₃ layer.

21. The semiconductor structure of claim 20 wherein:
the second monocrystalline perovskite oxide material is doped.

22. The semiconductor structure of claim 20 wherein:
the second monocrystalline perovskite oxide material is doped with niobium.

23. The semiconductor structure of claim 19 further comprising:
a second monocrystalline perovskite oxide material between the (BaSr)ZrO₃ layer and the InGaAs layer.

24. The semiconductor structure of claim 23 wherein:
the second monocrystalline perovskite oxide material is doped.

25. The semiconductor structure of claim 23 wherein:
the second monocrystalline perovskite oxide material is doped with niobium.

26. The semiconductor structure of claim 1 wherein:
the at least one monocrystalline compound semiconductor material comprises:
a first GaAs layer overlying the monocrystalline perovskite oxide material;
an AlGaAs layer overlying the first GaAs layer; and
a second GaAs layer overlying the AlGaAs layer.

27. The semiconductor structure of claim 26 wherein:
the transistor is a high electron mobility transistor.

28. The semiconductor structure of claim 1 wherein:
the at least one monocrystalline compound semiconductor material comprises:
an InGaAs layer overlying the monocrystalline perovskite oxide material;
an AlGaAs layer overlying the InGaAs layer; and
a GaAs layer overlying the AlGaAs layer.

29. The semiconductor structure of claim 28 wherein:
the transistor is a pseudomorphic high electron mobility transistor.

30. The semiconductor structure of claim 1 wherein:
the at least one monocrystalline compound semiconductor material comprises:
an InGaAs layer overlying the monocrystalline perovskite oxide material;
an AlInAs layer overlying the InGaAs layer; and
a InGaAs layer overlying the AlInAs layer.

31. The semiconductor structure of claim 30 wherein:
the transistor is a high electron mobility transistor.

32. The semiconductor structure of claim 30 wherein:
the transistor is a metamorphic high electron mobility transistor.

33. The semiconductor structure of claim 1 wherein:
the at least one monocrystalline compound semiconductor material comprises:
a first GaAs layer overlying the monocrystalline perovskite oxide material;
a second GaAs layer overlying the first GaAs layer;
an AlGaAs layer overlying the second GaAs layer;
a third GaAs layer overlying the AlGaAs layer; and
an InGaAs layer overlying the third GaAs layer.

34. The semiconductor structure of claim 33 wherein:
the transistor is a heterojunction bipolar transistor.

35. A semiconductor structure with selective doping comprising:
a monocrystalline silicon substrate;
an amorphous oxide material overlying the monocrystalline silicon substrate;
a monocrystalline perovskite oxide material overlying the amorphous oxide material;
at least one monocrystalline compound semiconductor material overlying the monocrystalline perovskite oxide material; and
a transistor in the at least one monocrystalline compound semiconductor material and comprising:
a first active region in the at least one monocrystalline compound semiconductor material and having a first conductivity level at a bias condition;
a second active region in the at least one monocrystalline compound semiconductor material and having a second conductivity level at the bias condition;
a third active region in the at least one monocrystalline compound semiconductor material, between the first and second active regions, and having a third conductivity level at the bias condition, the third conductivity level less than the first and second conductivity levels; and
a fourth active region in the at least one monocrystalline compound semiconductor material, between the first and third active regions, and having a fourth conductivity level at the bias condition, the fourth conductivity level less than the first and second conductivity levels.

36. The semiconductor structure of claim 35 wherein:
the first, second, third, and fourth conductivity levels substantially reduce a phase imbalance in the transistor compared to a similar transistor having first, second, third, and fourth active regions with substantially identical conductivity levels.

37. The semiconductor structure of claim 35 wherein:
the first, second, third, and fourth conductivity levels substantially reduce a temperature imbalance between the first, second, third, and fourth active regions compared to a similar transistor having first, second, third, and fourth active regions with substantially identical conductivity levels.

38. The semiconductor structure of claim 35 wherein:
the first, second, third, and fourth conductivity levels substantially reduce a current imbalance between the first, second, third, and fourth active regions compared to a similar transistor having first, second, third, and fourth active regions with substantially identical conductivity levels.

39. The semiconductor structure of claim 35 wherein:
the transistor further comprises:
an input; and
an output;
a first actual transmission length extends from the input of the transistor through the first active region to the output of the transistor;
a second actual transmission length extends from the input of the transistor through the second active region to the output of the transistor;
a third actual transmission length extends from the input of the transistor through the third active region to the output of the transistor and is shorter than the first and second actual transmission lengths;
a fourth actual transmission length extends from the input of the transistor through the fourth active region to the output of the transistor and is shorter than the first and second actual transmission lengths; and
the first, second, third, and fourth conductivity levels provide:
a first effective transmission length along the first actual transmission length;
a second effective transmission length along the second actual transmission length;
a third effective transmission length along the third actual transmission length; and
a fourth effective transmission length along the fourth actual transmission length and approximately equal to the first, second, and third effective transmission lengths.

40. The semiconductor structure of claim 35 wherein:
the second conductivity level is approximately equal to the first conductivity level; and
the fourth conductivity level is approximately equal to the third conductivity level.

41. The semiconductor structure of claim 35 wherein:
the transistor further comprises:
a first drain region adjacent to the first active region;
a second drain region between the third and fourth active regions;
a third drain region adjacent to the second active region;
a first source region between the first and fourth active region;
a second source region between the second and third active region;
a first gate electrode over the first active region;
a second gate electrode over the second active region;
a third gate electrode over the third active region;
a fourth gate electrode over the fourth active region;
a first drain electrode adjacent to the first gate electrode;
a second drain electrode between the third and fourth gate electrodes;
a third drain electrode adjacent to the second gate electrode;
a first source electrode between the first and fourth gate electrodes; and
a second source electrode between the second and third gate electrodes.

42. The semiconductor structure of claim 41 wherein:
the transistor further comprises:
a gate bus electrically coupled to the first, second, third, and fourth gate electrodes;
a source bus electrically coupled to the first and second source electrodes; and
a drain bus electrically coupled to the first, second, and third drain electrodes.

43. The semiconductor structure of claim 35 wherein:
the at least one monocrystalline compound semiconductor material comprises:
an InGaAs layer overlying the monocrystalline perovskite oxide material;
a (BaSr)ZrO₃ layer overlying the InGaAs layer;
a Sr(ZrTi)O₃ layer overlying the (BaSr)ZrO₃ layer; and
an InAlGaAs layer overlying the Sr(ZrTi)O₃ layer.

44. The semiconductor structure of claim 43 further comprising:
a second monocrystalline perovskite oxide material between the Sr(ZrTi)O₃ layer and the (BaSr)ZrO₃ layer; and
a third monocrystalline perovskite oxide material between the (BaSr)ZrO₃ layer and the InGaAs layer, wherein:
the second monocrystalline perovskite oxide material is doped with niobium; and
the third monocrystalline perovskite oxide material is doped with niobium.

45. The semiconductor structure of claim 35 wherein:
the transistor is a high electron mobility transistor; and
the at least one monocrystalline compound semiconductor material comprises:
a first GaAs layer overlying the monocrystalline perovskite oxide material;
an AlGaAs layer overlying the first GaAs layer; and
a second GaAs layer overlying the AlGaAs layer.

46. The semiconductor structure of claim 35 wherein:
the transistor is a pseudomorphic high electron mobility transistor; and
the at least one monocrystalline compound semiconductor material comprises:
an InGaAs layer overlying the monocrystalline perovskite oxide material;
an AlGaAs layer overlying the InGaAs layer; and
a GaAs layer overlying the AlGaAs layer.

47. The semiconductor structure of claim 35 wherein:
the transistor is a high electron mobility transistor; and
the at least one monocrystalline compound semiconductor material comprises:
a first InGaAs layer overlying the monocrystalline perovskite oxide material;
an AlInAs layer overlying the first InGaAs layer; and
a second InGaAs layer overlying the AlInAs layer.

48. The semiconductor structure of claim 35 wherein:
the transistor is a metamorphic high electron mobility transistor; and
the at least one monocrystalline compound semiconductor material comprises:
a first InGaAs layer overlying the monocrystalline perovskite oxide material;
an AlInAs layer overlying the first InGaAs layer; and
a second InGaAs layer overlying the AlInAs layer.

49. The semiconductor structure of claim 35 wherein:
the transistor is a heterojunction bipolar transistor; and
the at least one monocrystalline compound semiconductor material comprises:
a first GaAs layer overlying the monocrystalline perovskite oxide material;
a second GaAs layer overlying the first GaAs layer;
an AlGaAs layer overlying the second GaAs layer;
a third GaAs layer overlying the AlGaAs layer; and
an InGaAs layer overlying the third GaAs layer.

50. A process for fabricating a semiconductor structure with selective doping comprising:
providing a monocrystalline silicon substrate;
depositing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
epitaxially forming at least one monocrystalline compound semiconductor layer overlying the monocrystalline perovskite oxide film; and
forming a transistor in the at least one monocrystalline compound semiconductor layer and comprising active regions having different conductivity levels under substantially identical bias conditions.

51. The process of claim 50 further comprising:
selectively doping first portions of the at least one monocrystalline compound semiconductor layer; and
selectively doping second portions of the at least one monocrystalline compound semiconductor layer, wherein:
at least portions of the first and second portions of the at least one monocrystalline compound semiconductor layer form the active regions.

52. The process of claim 51 wherein:
selectively doping the first portions of the at least one monocrystalline compound semiconductor layer further comprises:
selectively doping the first portions of the at least one monocrystalline compound semiconductor layer while epitaxially forming the at least one monocrystalline compound semiconductor layer; and
selectively doping the second portions of the at least one monocrystalline compound semiconductor layer further comprises:
selectively doping the second portions of the at least one monocrystalline compound semiconductor layer while epitaxially forming the at least one monocrystalline compound semiconductor layer.

53. The process of claim 51 wherein:
selectively doping the first portions of the at least one monocrystalline compound semiconductor layer further comprises:
selectively doping the first portions of the at least one monocrystalline compound semiconductor layer after epitaxially forming the at least one monocrystalline compound semiconductor layer; and
selectively doping the second portions of the at least one monocrystalline compound semiconductor layer further comprises:
selectively doping the second portions of the at least one monocrystalline compound semiconductor layer after epitaxially forming the at least one monocrystalline compound semiconductor layer.

54. A semiconductor structure with selective doping comprising:
a semiconductor material; and
a transistor in the semiconductor material and comprising active regions having different conductivity levels under substantially identical bias conditions.

55. A semiconductor structure with selective doping comprising:
s semiconductor material; and
a transistor in the semiconductor material and comprising:
a first active region in the semiconductor material and having a first conductivity level at a bias condition;
a second active region in the semiconductor material and having a second conductivity level at the bias condition; and
a third active region in the semiconductor material, between the first and second active regions, and having a third conductivity level at the bias condition, the third conductivity level less than the first and second conductivity levels.

56. A process for fabricating a semiconductor structure with selective doping comprising:
providing a semiconductor layer; and
forming a transistor in the semiconductor layer and comprising active regions having different conductivity levels under substantially identical bias conditions.
